(19) United States
(12) Patent Application Publication
(10) Pub. No.: US 2023/0289677 A1
(43) Pub. Date: Sep. 14, 2023

(54) LOGISTICS AREA MANAGEMENT METHOD, LOGISTICS AREA MANAGEMENT SYSTEM, AND NON-TRANSITORY COMPUTER-READABLE STORAGE MEDIUM

(71) Applicant: TOYOTA JIDOSHA KABUSHIKI KAISHA, Toyota-shi (JP)

(72) Inventors: Nobuhisa OTSUKI, Tokyo-to (JP); Tomoyuki KAGA, Mishima-shi (JP); Hiroya MATSUBAYASHI, Tokyo-to (JP); Yuki ICHIOKA, Kawasaki-shi (JP); Takumi BAN, Tokyo-to (JP); Hideo HASEGAWA, Nagoya-shi (JP)

(73) Assignee: TOYOTA JIDOSHA KABUSHIKI KAISHA, Toyota-shi (JP)

(21) Appl. No.: 18/181,756

(22) Filed: Mar. 10, 2023

(30) Foreign Application Priority Data
Mar. 14, 2022 (JP) 2022-039617

(51) Int. Cl. G06Q 10/0631; B25J 9/16; G06Q 10/08

(52) U.S. Cl. CPC G06Q 10/063114; B25J 9/1664; G06Q 10/08

(57) ABSTRACT

The method of the present disclosure is a management method for a logistics area with a work line constituted of a plurality of work subjects. The method comprises: simulating, using a digital twin, a work space in which the plurality of work subjects work; monitoring an actual movement of each of the plurality of work subjects in the work space; and displaying each of the plurality of work subjects on a screen simulating the work space as a heat map of which a color is changed in accordance with a degree of deviation between a movement simulated using the digital twin and a monitored actual movement.

### CROSS-REFERENCE TO RELATED APPLICATION

The present application claims priority under 35 U.S.C. § 119 to Japanese Patent Application No. 2022-039617, filed Mar. 14, 2022, the disclosure of which is incorporated herein by reference in its entirety.

### BACKGROUND

### Field

The present disclosure relates to a technique suitable for use in management of a logistics area with a work line constituted of a plurality of work subjects.

### Background Art

A logistics area has a work line constituted of a plurality of work subjects such as robots and workers. Recently, it has been considered to use simulation for management of such a logistics area. For example, JP2007-041950A discloses a technique of comparing a simulation result such as a lead time with actual data of an actual line and displaying a comparison result.

However, when the prior art described in JP2007-041950A is used for management of the logistics area, there is room for improvement in a method of displaying a comparison result between a simulation result and actual data. In the management of the logistics area, it is desirable to be able to easily grasp where a work subject that does not move according to the simulation is in the work space and how much the work subject deviates from the simulation.

In addition to JP2007-041950A, JP2020-113123A, JP2004-196553A, JP2020-157442A, and JP2005-056087A can be exemplified as documents showing the technical level of the technical field related to the present disclosure.

### SUMMARY

The present disclosure has been made in view of the above-described problems. An object of the present disclosure is to provide a technique that uses simulation for management of a logistics area with a work line constituted of a plurality of work subjects, and can easily grasp where a work subject that does not move according to the simulation is in a work space and how much the work subject deviates from the simulation.

The present disclosure provides a logistics area management method and a logistics area management system as a logistics area management technique for achieving the above object.

The logistics area management method of the present disclosure is a management method for a logistics area with a work line constituted of a plurality of work subjects. The logistics area management method of the present disclosure comprises simulating, using a digital twin, a work space in which the plurality of work subjects work, and monitoring an actual movement of each of the plurality of work subjects in the work space. Furthermore, the logistics area management method of the present disclosure comprises displaying each of the plurality of work subjects on a screen simulating the work space as a heat map of which a color is changed in accordance with a degree of deviation between a movement simulated using the digital twin and a monitored actual movement.

The logistics area management system of the present disclosure is a management system for a logistics area with a work line constituted of a plurality of work subjects. The logistics area management system of the present disclosure comprises a digital twin simulator, a monitoring device, and a display device. The digital twin simulator is configured to simulate a work space in which the plurality of work subjects work. The monitoring device is configured to monitor an actual movement of each of the plurality of work subjects in the work space. The display device is configured to display each of the plurality of work subjects on a screen simulating the work space as a heat map of which a color is changed in accordance with a degree of deviation between a movement simulated by the digital twin simulator and an actual movement monitored by the monitor.

According to the logistics area management technique of the present disclosure, the manager of the logistics area can easily grasp where the work subject that does not move according to the simulation is in the work space and how much the work subject deviates from the simulation, from the color distribution state of the heat map displayed on the screen simulating the work space.

In the logistics area management technique of the present disclosure, the work speed of each of the plurality of work subjects may be measured, and the color of the heat map may be changed in accordance with the difference between a work speed simulated using the digital twin and a measured actual work speed. This makes it possible to easily specify the work subject which is generating delay in the work. Further, it is possible to recognize the occurrence of some abnormality in the work space from the presence of such a work subject.

In addition, in the logistics area management technique of the present disclosure, when the plurality of work subjects includes a plurality of logistics robots, the braking action of each of the plurality of logistics robots may be detected, and the color of the heat map may be changed in accordance with a difference in intensity or frequency between a braking action simulated using the digital twin and a detected actual braking action. This makes it possible to easily specify a logistics robot that is slowing down or a logistics robot that is making a jerky movement. Further, it is possible to recognize the occurrence of some abnormality in the work space from the presence of such a logistics robot.

Furthermore, in the logistics area management technique of the present disclosure, the operation range of each of the plurality of work subjects may be measured, and the color of the heat map may be changed in accordance with a difference between an operation range simulated using the digital twin and a measured actual operation range. This makes it possible to easily specify a work subject performing a useless movement or a work subject performing an unexpected movement. Further, it is possible to recognize the occurrence of some abnormality in the work space from the presence of such a work subject.

Furthermore, in the logistics area management technique of the present disclosure, the flow line of each of the plurality of work subjects may be measured, and the color of the heat map may be changed in accordance with a degree of deviation between a flow line simulated using the digital twin and a measured actual flow line. This makes it possible to easily specify a work subject performing a useless movement or a work subject performing an unexpected movement. Further, it is possible to recognize the occurrence of some abnormality in the work space from the presence of such a work subject.

In addition, the present disclosure provides a program for achieving the above object. The program of the present disclosure is a program for causing a computer to manage a logistics area with a work line constituted of a plurality of work subjects. The program of the present disclosure is configured to cause the computer to execute acquiring simulation data obtained by simulating, using a digital twin, a work space in which the plurality of work subjects work, and acquiring monitored data obtained by monitoring an actual movement of each of the plurality of work subjects in the work space. Further, the program of the present disclosure is configured to cause the computer to execute synchronizing and comparing the simulation data and the monitored data to generate display data for displaying each of the plurality of work subjects on a screen simulating the work space as a heat map of which a color is changed in accordance with a degree of deviation between a movement simulated using the digital twin and a monitored actual movement. The program of the present disclosure may be provided by being stored on a non-transitory computer-readable storage medium.

As described above, according to the logistics area management technique of the present disclosure, the manager of the logistics area can easily grasp where the work subject who does not move according to the simulation is in the work space and how much the work subject deviates from the simulation by the color distribution state of the heat map displayed on the screen simulating the work space.

### BRIEF DESCRIPTION OF THE DRAWINGS

FIG. 1 is a diagram illustrating a configuration of a logistics area management system according to an embodiment of the present disclosure.

FIG. 2 is a diagram showing functions of the display constituting the management system shown in FIG. 1.

FIG. 3 is a diagram illustrating an example of a heat map displayed on a display terminal.

FIG. 4 is a diagram illustrating a first method of determining the display color of the heat map.

FIG. 5 is a diagram illustrating a second method of determining the display color of the heat map.

FIG. 6 is a diagram illustrating a third method of determining the display color of the heat map.

FIG. 7 is a diagram illustrating a fourth method of determining the display color of the heat map.

### DETAILED DESCRIPTION

Hereinafter, an embodiment of a logistics area management method, a logistics area management system, and a program of the present disclosure will be described with reference to the drawings. However, in the embodiment described below, when a numerical value such as the number, quantity, amount, range, or the like of each element is mentioned, the idea according to the present disclosure is not limited to the mentioned numerical value except for a case where the numerical value is clearly specified in particular or a case where the numerical value is obviously specified to the numerical value in principle. In addition, a structure or the like described in the following embodiment is not always necessary to the idea according to the present disclosure except for a case where the structure or the like is clearly specified in particular or a case where the structure or the like is obviously specified in principle.

### 1. Configuration of Logistics Area Management System

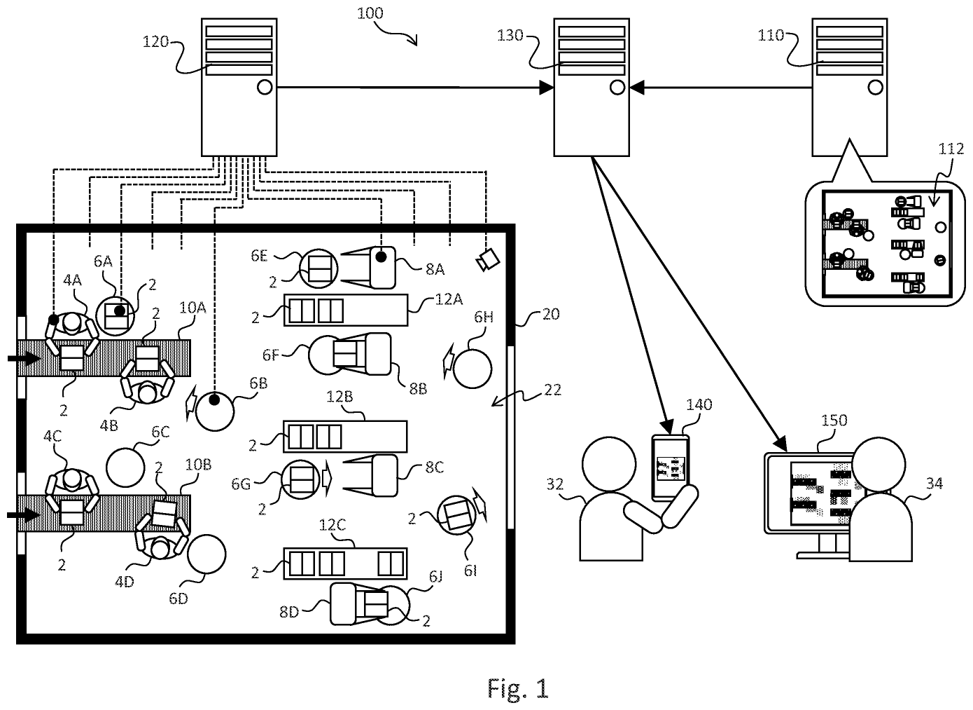

FIG. 1 is a diagram illustrating a configuration of a logistics area management system according to an embodiment of the present disclosure. First, a logistics area to be managed by the management system 100 will be described.

The logistics area managed by the management system 100 is a logistics area with a work line constituted of a plurality of work subjects. Examples of such a logistics area include a relay station (for example, a home delivery office, a collection station in a large-scale apartment house, or the like) for sorting packages, a work place for collecting and sorting waste, a physical distribution zone for receiving parts and shipping products in a manufacturing plant, and the like.

The logistics area 20 illustrated in FIG. 1 is a relay station for sorting loads 2. The logistics area 20 is equipped with conveyors 10A-10B used for sorting incoming loads 2. The logistics area 20 is also equipped with racks 12A-12C for temporary storage of sorted loads 2. The work subjects of the logistics area 20 are workers 4A-4D, transfer robots 6A-6J, and picking robots 8A-8D. These work subjects constitute a work line for sorting and carrying out the loads 2 carried into the logistics area 20.

The conveyors 10A-10B have a mixed flow of loads 2 of various types and destinations. The workers 4A-4D select and pick up the loads 2 from the conveyors 10A-10B. The load 2 to be taken out by each of the workers 4A-4D is determined in advance according to the type and destination of the load 2.

The transfer robots 6A-6G are logistics robots that receive the loads 2 selected and taken out by the workers 4A-4D and transfer the loads 2 to the picking robots 8A-8D. The load 2 to be received by each of the transfer robots 6A-6G is determined in advance according to the type and destination of the load 2. The transferring destination of each of the transfer robots 6A-6G is also determined in advance according to the type and destination of the load 2.

The picking robots 8A-8D are working robots that store the loads 2 received from the transfer robots 6A-6G into the racks 12A-12C. The place where each of the picking robots 8A-8D should store the load 2 is determined in advance according to the type and destination of the load 2. Further, the picking robots 8A-8D select and take out the loads 2 from the racks 12A-12C. The load 2 to be picked up by each picking robot 8A-8D is predetermined by a carry-out schedule.

The transfer robots 6H-6J receive the loads 2 selected and taken out by the picking robots 8A-8D and transfer the loads 2 to the next relay station outside the logistics area 20. The load 2 to be received by each transfer robot 6H-6J is predetermined by the carry-out schedule. The transferring destination of each of the transfer robots 6H-6J is also determined in advance by the carry-out schedule.

The management system 100 includes a digital twin simulator 110, a monitoring device 120, and a display device 130. The logistics area management method according to the embodiment of the present disclosure is executed by cooperation of the digital twin simulator 110, the monitoring device 120, and the display device 130 that constitute the management system 100.

Each of the digital twin simulator 110, the monitoring device 120, and the display device 130 may be an independent computer or a virtual computer built in one computer. The management system 100 may be installed on the site of the logistics area 20 or may be installed on a cloud. In addition, when each of the digital twin simulator 110, the monitoring device 120, and the display device 130 is an independent computer, a part of the computers may be installed on the site of the logistics area 20 and the remaining computers may be installed on the cloud.

The digital twin simulation device 110 is a computer for realizing a digital twin of the logistics area 20 by simulation. On the virtual space of the digital twin simulator 110, a virtual work space 112 simulating a work space (hereinafter referred to as an actual work space) 22 in which work subjects work in the logistics area 20 is constructed. The digital twin simulator 110 is configured to simulate in real time the movement of each of the work subjects in the virtual work space 112. The digital twin simulator 110 is input with information related to actual work conditions of the logistics area 20 such as a load amount, destinations (variation) of loads, the number of workers, and the number of standby robots. In the example illustrated in FIG. 1, all of the workers 4A-4D, the transfer robots 6A-6J, and the picking robots 8A-8D are defined in the virtual work space 112. The digital twin simulator 110 transmits real-time simulation data generated by the simulation to the display device 130.

The monitoring device 120 is a computer that monitors the work line of the logistics area 20. The monitoring device 120 is configured to monitor respective actual movements of the workers 4A-4D, the transfer robots 6A-6J, and the picking robots 8A-8D in the actual work space 22 of the logistics area 20. Various means including sensors are used to monitor the movements of the work subjects. For example, optical monitoring means such as a visible light camera and an infrared camera are installed at various locations in the actual work space 22. Moreover, a wireless tag (BLE, RFID, etc.) that is an electromagnetic monitoring means is attached to the load 2. In addition, a millimeter wave radar for detecting a living body is installed in the vicinity of the work space of the workers 4A-4D. Further, each of the transfer robots 6A-6J and the picking robots 8A-8D is provided with a self-position identifying means by which the work subject itself measures and notifies the position thereof. The self-position identification method includes simultaneous localization and mapping (SLAM) by LiDAR, designation from a peripheral feature point by a camera, integration by a wheel encoder, instantaneous moving speed estimation, and the like. The monitoring device 120 collects data from the logistics area 20 in real time to generate monitored data, and transmits the monitored data to the display device 130.

The display device 130 is a computer that generates display data to be displayed to the managers 32 and 34 of the logistics area 20. The display device 130 generates display data using the simulation data received from the digital twin simulator 110 and the monitored data received from the monitoring device 120. The display data is displayed on the display terminals 140 and 150. The display terminal 140 is a mobile terminal such as a smartphone, and the display terminal 150 is a desktop PC with a display. The display device 130 is connected to display terminals 140 and 150 via a communication network. Conceptually, the display terminals 140 and 150 can also be regarded as a part of the display device 130. The manager 32 carrying the display terminal 140 can perform management work while viewing the display terminal 140 at the site of the logistics area 20. The manager 34 sitting in front of the display terminal 150 can perform management work while looking at the display terminal 150 at a place away from the logistics area 20.

### 2. Function of Display Device

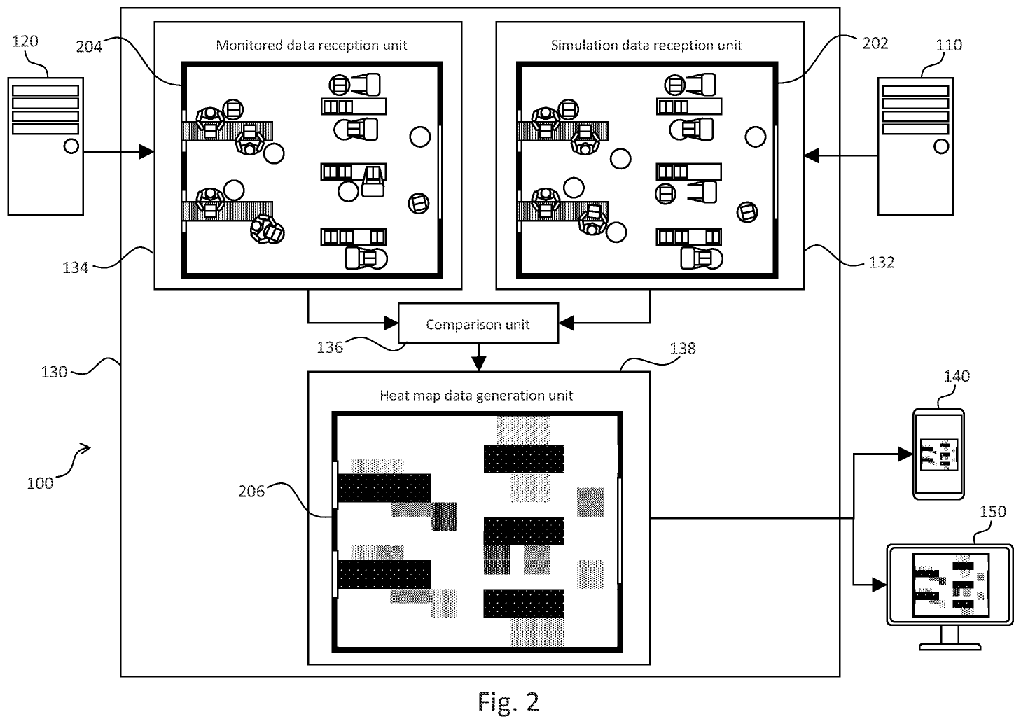

Next, the function of the display device 130 will be described. FIG. 2 is a diagram showing functions of the display device 130. The display device 130 includes a simulation data reception unit 132, a monitored data reception unit 134, a comparison unit 136, and a heat map data generation unit 138. These elements constituting the display device 130 are functions of the display device 130 realized when a program stored in a memory of the display device 130 is executed by a processor of the display device 130.

The simulation data reception unit 132 receives simulation data 202 generated by the simulation from the digital twin simulator 110. The monitored data reception unit 134 receives the monitored data 204 obtained from the logistics area 20 in real time from the monitoring device 120.

The comparison unit 136 acquires the simulation data 202 from the simulation data reception unit 132 and acquires the monitored data 204 from the monitored data reception unit 134. The comparison unit 136 synchronizes and compares the simulation data 202 and the monitored data 204. More specifically, the comparison unit 136 compares the movement simulated by the digital twin simulator 110 with the actual movement monitored by the monitoring device 120 for each of the work subjects in the logistics area 20, and calculates the degree of deviation between them. The comparison result by the comparison unit 136, that is, the information on the degree of deviation between the simulated movement and the actual movement for each of the work subjects is transmitted from the comparison unit 136 to the heat map data generation unit 138.

The heat map data generation unit 138 generates heat map data 206 based on the comparison result acquired from the comparison unit 136. The heat map data 206 is data for displaying each of the work subjects as a heat map of which the color is changed for each work subject on a screen simulating the work space 22 of the logistics area 20. The heat map data generation unit 138 determines the color of the work subject to be displayed on the screen for each work subject in accordance with the degree of deviation between the simulated movement and the actual movement, that is the comparison result. The relationship between the degree of deviation and the display color of the heat map is defined in advance. The display device 130 transmits the heat map data 206 to the display terminals 140 and 150 as display data.

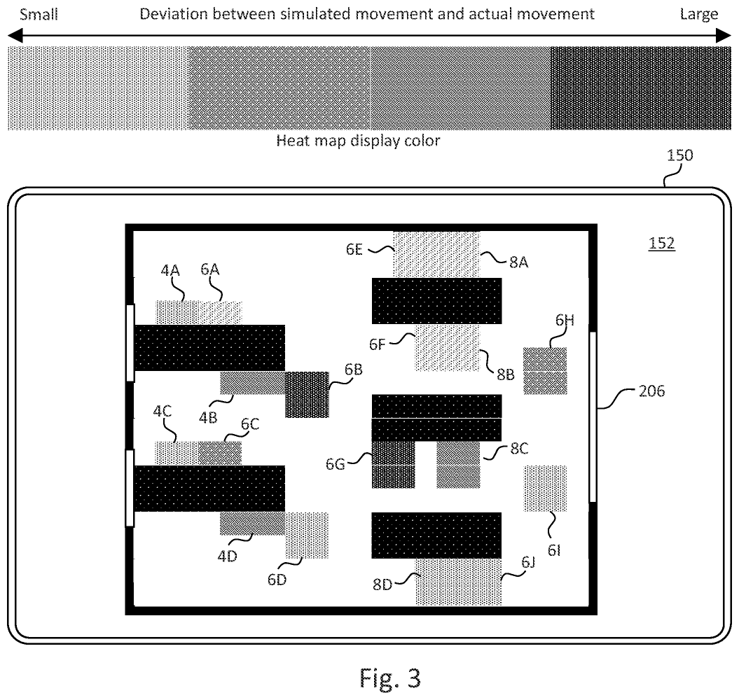

FIG. 3 is a diagram illustrating an example of the heat map displayed on the display terminal 150. The display terminal 150 displays a screen 152 that simulates the work space 22 of the logistics area 20. The screen 152 shows the heat map of each of the workers 4A-4D, transfer robots 6A-6J, and picking robots 8A-8D, which are work subjects. The display color of each work subject is determined by the degree of deviation between the simulated movement and the actual movement. In the example shown in FIG. 3, each work subject is displayed in a darker color as the deviation is larger. The display color may be changed continuously according to the degree of deviation, or may be changed stepwise as in the example shown in FIG. 3. When the heat map is displayed in color, the heat map may be displayed in red when the deviation is large, may be displayed in green when the deviation is small, and may be displayed in yellow when the deviation is intermediate. A screen similar to the screen 152 of the display terminal 150 is also displayed on the display terminal 140.

The managers 32 and 34 can check the color distribution state of the heat map on the screen displayed on the display terminals 140 and 150. The color distribution state of the heat map changes depending on the work state of each work subject working in the work space 22. By the color distribution state of the heat map displayed on the screen, the managers 32 and 34 can easily grasp where the work subject who does not move according to the simulation is in the work space 22 and how much the work subject deviates from the simulation.

In the next section, a method of determining the display color of the heat map, in particular, “deviation between a simulated movement and an actual movement” for determining the display color will be described in detail with a specific example.

### 3. Method of Determining Display Color of Heat Map

### 3-1. First Method

In the first method, the work speed of each of all work subjects working in the work space 22 is measured by the monitoring device 120. The comparison unit 136 of the display device 130 calculates the difference between the work speed simulated by the digital twin simulator 110 and the actual work speed measured by the monitoring device 120. The heat map data generation unit 138 of the display device 130 changes the color of the heat map according to the difference in the work speed.

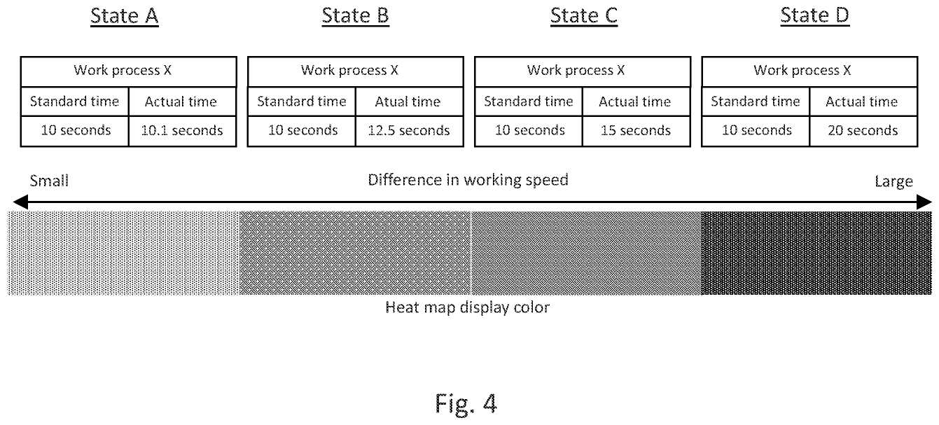

FIG. 4 shows the standard time and the actual time of the work process X for each of the states A to D of a certain work subject. The standard time is a time per cycle of the work process X obtained by the simulation by the digital twin simulator 110. The actual time is the time actually required for one cycle of the work process X measured by the monitoring device 120. The difference between the standard time and the actual time represents the difference between the simulated work speed and the actual work speed. In the example shown in FIG. 4, the difference in work speed increases in the order of state A, state B, state C, and state D, and the display color of the heat map is changed accordingly.

According to the first method, it is possible to easily specify the work subject in which the delay occurs in the work. Further, it is possible to recognize the occurrence of some abnormality in the work space 22 from the presence of such a work subject.

### 3-2. Second Method

In a second method, the braking action of each of the transfer robots 6A-6J working in the working space 22 is detected by the monitoring device 120. The comparison unit 136 of the display device 130 calculates the difference in intensity or frequency between the braking action simulated by the digital twin simulator 110 and the actual braking action detected by the monitoring device 120. The heat map data generation unit 138 of the display device 130 changes the color of the heat map in accordance with the difference in the intensity or the frequency of the braking action.

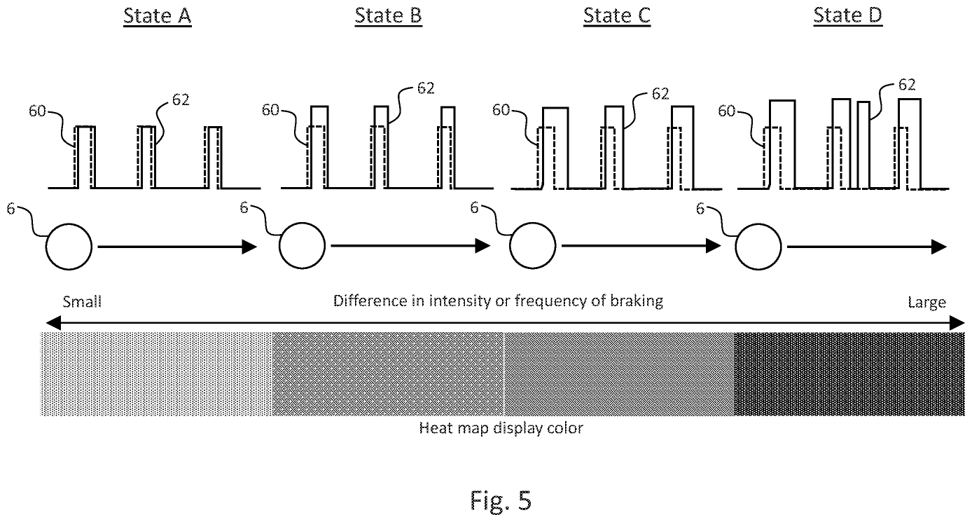

FIG. 5 is a time chart showing the braking action of a certain transfer robot 6 in states A to D. The vertical axis of each time chart indicates the intensity of the braking action. In state A, the simulated braking action 60 and the actual braking action 62 substantially coincide with each other. Therefore, the display color of the heat map is the lightest color.

In state B, the actual braking action 62 is stronger than the simulated braking action 60. Therefore, the display color of the heat map is darker in state B than in state A.

In state C, the braking time per one action is longer than that in state B. In other words, a stronger braking is applied in state C than in state B. Therefore, the display color of the heat map is darker in state C than in state B.

In state D, the frequency of the braking action is increased by one as compared with state C. Therefore, the display color of the heat map is darker in state D than in state C. In other words, in the example shown in FIG. 5, the difference in the intensity or the frequency of braking increases in the order of state A, state B, state C, and state D, and the display color of the heat map is changed accordingly.

According to the second method, it is possible to easily specify a transfer robot that is slowing down or a transfer robot that is making a jerky movement. Further, it is possible to recognize the occurrence of some abnormality in the work space 22 from the presence of such a transfer robot.

### 3-3. Third Method

In the third method, the operation range of each of all work subjects working in the work space 22 is measured by the monitoring device 120. The comparison unit 136 of the display device 130 calculates the difference between the operation range simulated by the digital twin simulator 110 and the actual operation range measured by the monitoring device 120. The heat map data generation unit 138 of the display device 130 changes the color of the heat map according to the difference between the operation ranges.

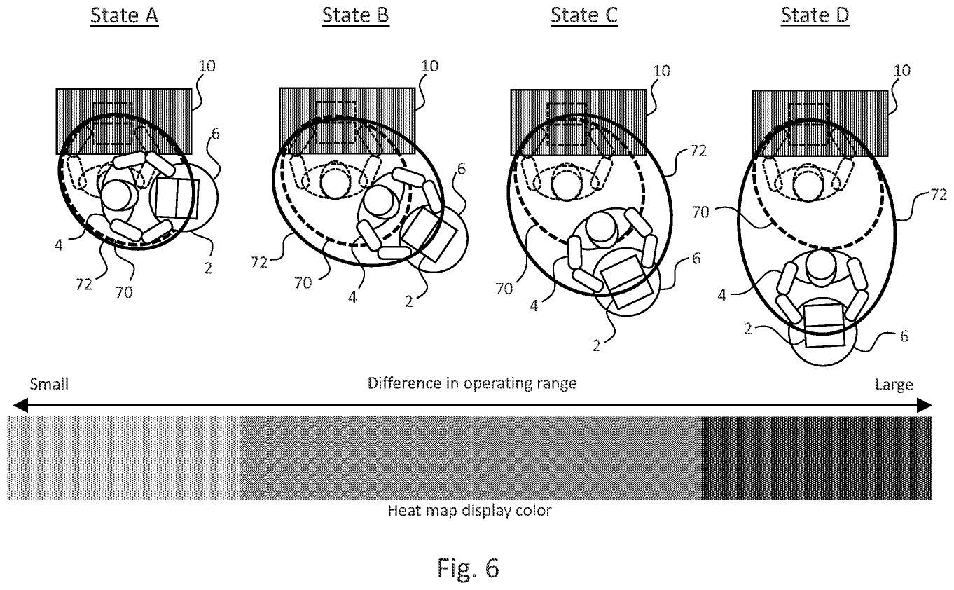

FIG. 6 schematically illustrates operation ranges of a certain worker 4 in states A to D. The operation range of the worker 4 is affected by the standby position of the transfer robot 6 that delivers the load 2. In state A, the transfer robot 6 stands by at the normal standby position. Therefore, in state A, the operation range 70 of the worker 4 by the simulation and the actual operation range 72 of the worker 4 substantially coincide with each other. Therefore, the display color of the heat map is the lightest color.

In state B, the transfer robot 6 stands by at a position away from the worker 4 obliquely rearward from the normal standby position. Therefore, in state B, the actual operation range 72 of the worker 4 is larger than the operation range 70 of the worker 4 by the simulation. Therefore, the display color of the heat map is darker in state B than in state A.

In state C, the transfer robot 6 stands by at a position further away from the worker 4 rearward from the standby position in state B. Therefore, the actual operation range 72 of the worker 4 in state C is further larger than the operation range 72 of the worker 4 in state B. Therefore, the display color of the heat map is darker in state C than in state B.

In state D, the transfer robot 6 stands by at a position further away from the worker 4 rearward from the standby position in state C. Therefore, the actual operation range 72 of the worker 4 in state D is further larger than the operation range 72 of the worker 4 in state C. Therefore, the display color of the heat map is darker in state D than in state C. In other words, in the example shown in FIG. 6, the difference between the operation ranges increases in the order of state A, state B, state C, and state D, and the display color of the heat map is changed accordingly.

According to the third method, it is possible to easily specify a work subject performing an unnecessary movement or a work subject performing an unexpected movement. Further, it is possible to recognize the occurrence of some abnormality in the work space 22 from the presence of such a work subject.

### 3-4. Fourth Method

In the fourth method, the respective flow lines of all work subjects working in the work space 22 are measured by the monitoring device 120. The comparison unit 136 of the display device 130 calculates the degree of deviation between the flow line simulated by the digital twin simulator 110 and the actual flow line measured by the monitoring device 120. The heat map data generation unit 138 of the display device 130 changes the color of the heat map in accordance with the degree of deviation between the flow lines.

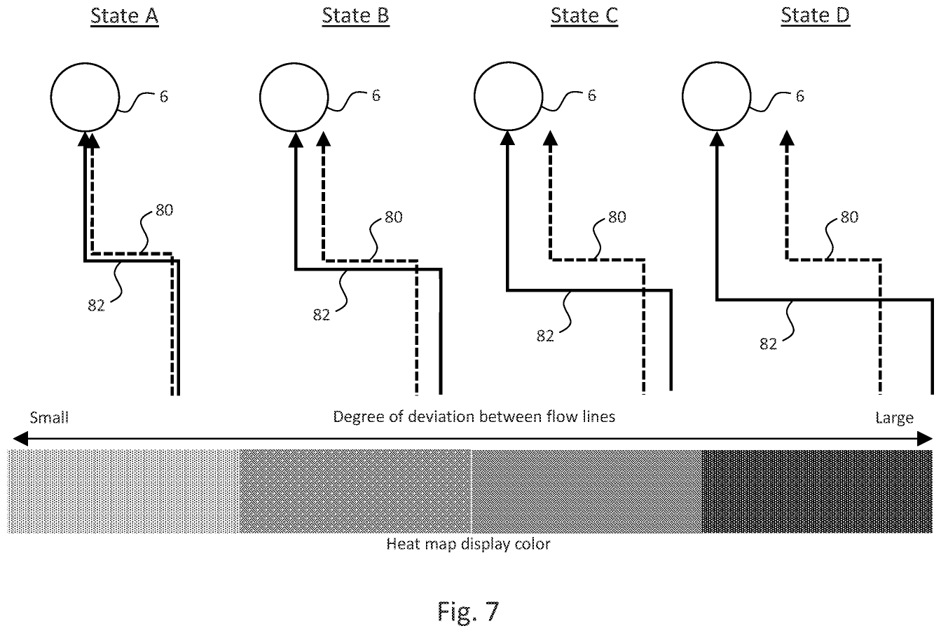

FIG. 7 schematically illustrates flow lines of a certain transfer robot 6 in states A to D. In state A, the simulated flow line 80 of the transfer robot 6 substantially coincides with the actual flow line 82 of the transfer robot 6. Therefore, the display color of the heat map is the lightest color.

In state B, there is a deviation between the simulated flow line 80 of the transfer robot 6 and the actual flow line 82 of the transfer robot 6. Therefore, the display color of the heat map is darker in state B than in state A.

In state C, the deviation between the simulated flow line 80 of the transfer robot 6 and the actual flow line 82 of the transfer robot 6 is larger than the deviation in state B. Therefore, the display color of the heat map is darker in state C than in state B.

In state D, the deviation between the simulated flow line 80 of the transfer robot 6 and the actual flow line 82 of the transfer robot 6 is larger than the deviation in state C. Therefore, the display color of the heat map is darker in state D than in state C. That is, in the example shown in FIG. 7, the degree of deviation between the flow lines increases in the order of state A, state B, state C, and state D, and the display color of the heat map is changed accordingly.

According to the fourth method, it is possible to easily specify a work subject performing an unnecessary movement or a work subject performing an unexpected movement. Further, it is possible to recognize the occurrence of some abnormality in the work space 22 from the presence of such a work subject.

What is claimed is:

1. A management method for a logistics area with a work line constituted of a plurality of work subjects, the management method comprising:
simulating, using a digital twin, a work space in which the plurality of work subjects work;
monitoring an actual movement of each of the plurality of work subjects in the work space; and
displaying each of the plurality of work subjects on a screen simulating the work space as a heat map of which a color is changed in accordance with a degree of deviation between a movement simulated using the digital twin and a monitored actual movement.

2. The management method according to claim 1, further comprising:
measuring a work speed of each of the plurality of work subjects; and
changing the color of the heat map in accordance with a difference between a work speed simulated using the digital twin and a measured actual work speed.

3. The management method according to claim 1, wherein the plurality of work subjects includes a plurality of logistics robots, the management method further comprising:
detecting a braking action of each of the plurality of logistics robots; and
changing the color of the heat map in accordance with a difference in intensity or frequency between a braking action simulated using the digital twin and a detected actual braking action.

4. The management method according to claim 1, further comprising:
measuring an operation range of each of the plurality of work subjects; and
changing the color of the heat map in accordance with a difference between an operation range simulated using the digital twin and a measured actual operation range.

5. The management method according to claim 1, further comprising:
measuring a flow line of each of the plurality of work subjects; and
changing the color of the heat map in accordance with a degree of deviation between a flow line simulated using the digital twin and a measured actual flow line.

6. A management system for a logistics area with a work line constituted of a plurality of work subjects, the management system comprising:
a digital twin simulator configured to simulate a work space in which the plurality of work subjects work;
a monitoring device configured to monitor an actual movement of each of the plurality of work subjects in the work space; and
a display device configured to display each of the plurality of work subjects on a screen simulating the work space as a heat map of which a color is changed in accordance with a degree of deviation between a movement simulated by the digital twin simulator and an actual movement monitored by the monitoring device.

7. The management system according to claim 6, wherein
the monitoring device is configured to measure a work speed of each of the plurality of work subjects, and
the display device is configured to change the color of the heat map in accordance with a difference between a work speed simulated by the digital twin simulator and an actual work speed measured by the monitoring device.

8. The management system according to claim 6, wherein
the plurality of work subjects includes a plurality of logistics robots,
the monitoring device is configured to detect a braking action of each of the plurality of logistics robots, and
the display device is configured to change the color of the heat map in accordance with a difference in intensity or frequency between a braking action simulated by the digital twin simulator and an actual braking action detected by the monitoring device.

9. The management system according to claim 6, wherein
the monitoring device is configured to measure an operation range of each of the plurality of work subjects, and
the display device is configured to change the color of the heat map in accordance with a difference between an operation range simulated by the digital twin simulator and an actual operation range measured by the monitoring device.

10. The management system according to claim 6, wherein
the monitoring device is configured to measure a flow line of each of the plurality of work subjects, and
the display device is configured to change the color of the heat map in accordance with a degree of deviation between a flow line simulated by the digital twin simulator and an actual flow line measured by the monitoring device.

11. A non-transitory computer-readable storage medium storing a program for causing a computer to execute processing for managing a logistics area with a work line constituted of a plurality of work subjects, the processing comprising:
acquiring simulation data obtained by simulating, using a digital twin, a work space in which the plurality of work subjects work;
acquiring monitored data obtained by monitoring an actual movement of each of the plurality of work subjects in the work space; and
synchronizing and comparing the simulation data and the monitored data to generate display data for displaying each of the plurality of work subjects on a screen simulating the work space as a heat map of which a color is changed in accordance with a degree of deviation between a movement simulated using the digital twin and a monitored actual movement.
